(19) United States
(12) Patent Application Publication
(10) Pub. No.: US 2010/0327447 A1
(43) Pub. Date: Dec. 30, 2010

(54) Method of manufacturing semiconductor device and semiconductor device

(75) Inventors: Manabu Iguchi, Kanagawa (JP); Hirokazu Aizawa, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki-shi (JP)

(21) Appl. No.: 12/801,097

(22) Filed: May 21, 2010

(30) Foreign Application Priority Data
Jun. 25, 2009 (JP) 2009-151129

(51) Int. Cl. H01L 23/532; H01L 21/768

(52) U.S. Cl. 257/751; 438/653; 257/E21.584; 257/E23.155

(57) ABSTRACT

A method of manufacturing a semiconductor device includes forming a barrier metal film including a high melting point metal in a concave portion formed in an insulating film formed over a substrate; forming a seed alloy film including copper and an impurity metal different from the copper over the barrier metal film so as to fill a portion of the concave portion; forming a plated metal film containing copper as a major ingredient over the seed alloy film so as to fill the concave portion; first heat-treating the seed alloy film and the plated metal film at 200° C. or higher and for ten minutes or less; removing the plated metal film, the seed alloy film, and the barrier metal film which are exposed to the outside of the concave portion, after the first heat-treating; and second heat-treating the seed alloy film and the plated metal film.

The application is based on Japanese patent application No. 2009-151129, the content of which is incorporated hereinto by reference.

### BACKGROUND

1. Technical Field

The present invention relates to a method of manufacturing a semiconductor device and the semiconductor device.

2. Related Art

From the request for high integration of semiconductor devices in recent years, copper having a low resistance has been widely used as a material for interconnects, plugs, pads and the like. However, there are problems in that electromigration or stress migration may occur in the interconnects in which copper is used. Although the copper film that constitutes the copper interconnects is typically formed by a plating method. When the copper interconnects is formed by a plating method, the copper film is formed so that a large number of copper particles having a polycrystalline structure are collected. When voltage is applied to the copper interconnects having such a structure, substance migration happens through the grain boundary of the copper particles, and as a result, electromigration occurs. In addition, stress migration occurs caused by voids generated in the interconnects.

Japanese Unexamined Patent Application Publication No. 2007-335578 discloses a configuration in which the interconnect is formed using a seed film which is composed of copper containing aluminum. In addition, this document discloses a configuration in which aluminum included in the seed film is diffused into the copper film.

Japanese Unexamined Patent Application Publication No. 2008-147252 discloses a technique in which a Cu film is formed on a CuAl alloy seed film, an annealing process is performed at a temperature equal to or greater than 100° C. and equal to or less than 450° C., and Al in the CuAl alloy seed film is diffused into the Cu film. In addition, this document discloses that the Cu film is formed by a plating method and then the annealing process is performed at a temperature equal to or greater than 100° C. and equal to or less than 450° C., so that diffusion of Al into the Cu film formed by grain growth of Cu and the plating method arises, whereby after the annealing process, the interface of the CuAl alloy seed film and the Cu film is not necessarily obvious and may be formed as one grain.

Japanese Unexamined Patent Application Publication No. 2005-050859 discloses a configuration in which an aluminum film is formed on the interconnect which is a copper film, and an alloy film made of CuAl which is an alloy of copper and aluminum is formed by reaction of the copper film and the aluminum film by performing heat treatment.

Alternatively to the configuration that a barrier metal film is formed using a high melting point metal, Japanese Unexamined Patent Application Publication No. 2007-96241 discloses a configuration in which an auxiliary film made of a Cu alloy containing Mn is formed within a concave portion of an insulating interlayer, and heat treatment is performed, whereby a reactant layer of Mn and an element such as Si in the insulating interlayer is formed between the copper interconnect and the insulating interlayer. This reactant layer functions as an adhesion layer of the copper and the insulating interlayer and a diffusion barrier film. In addition, this document discloses that before the heat treatment, an adhesion layer composed of Ag and the like is formed between the insulating interlayer and the auxiliary film in order to raise adhesion of the copper interconnect and the insulating interlayer.

The inventors have studied a method of using an alloy film of copper including, for example, Al as a seed metal film, as disclosed in Japanese Unexamined Patent Application Publication No. 2007-335578 or Japanese Unexamined Patent Application Publication No. 2008-147252. However, according to the above method, it has been found that it is impossible to control a region having a high concentration of impurity metals to be formed at the desired place.

Moreover, in the method as disclosed in Japanese Unexamined Patent Application Publication No. 2005-050859, after the interconnect is formed, it is further required to form, heat-treat and etch the aluminum film, which results in an increase in the number of processes.

Furthermore, in the method as disclosed in Japanese Unexamined Patent Application Publication No. 2007-96241, there may be a concern that the diffusion barrier function of the copper film would not be sufficient.

### SUMMARY

In one embodiment, there is provided a method of manufacturing a semiconductor device including: forming a barrier metal film including a high melting point metal in a concave portion formed in an insulating film formed over a substrate; forming a seed alloy film including copper and an impurity metal different from the copper over the barrier metal film so as to fill a portion of the concave portion; forming a plated metal film containing copper as a major ingredient over the seed alloy film so as to fill the concave portion; first heat-treating the seed alloy film and the plated metal film at 200° C. or higher and for ten minutes or less; removing the plated metal film, the seed alloy film, and the barrier metal film which are exposed to the outside of the concave portion, after the first heat-treating; and second heat-treating the seed alloy film and the plated metal film.

In another embodiment, there is provided a semiconductor device including: a substrate; an insulating film formed over the substrate; a barrier metal film which is formed in the bottom face and the sidewall of a concave portion formed in the insulating film, and contains a high melting point metal; and an interconnect metal film formed over the barrier metal film within the concave portion, and containing copper as a major ingredient and an impurity metal different from the copper, grains of copper being formed therein. The interconnect metal film is configured so that in a stacking direction, the average concentration of the impurity metal in the surface thereof is higher than the concentration of the impurity metal in the central portion thereof, and the concentration of the impurity metal in the grain boundary is higher than the concentration of the impurity metal in the inside of the grains, the interconnect metal film having a concentration profile in which the concentration of the impurity metal becomes high, in the surface, extending from the central portion of the width direction to the sidewall.

The inventors have studied a method of forming a region having a high concentration of impurity metals other than copper, such as Al, in the side and the bottom face of the interconnect, and the surface of the interconnect to thereby improve electromigration lifetime or stress migration lifetime. However, as described above, according to the above method as described in the above documents, it has been found that it is impossible to control a region having a high concentration of impurity metals to be formed at the desired place.

Heretofore, after the seed metal film is formed and the plated film is formed, annealing for a long period of time has been performed, before a redundant metal film is removed by chemical mechanical polishing (CMP). For this reason, the impurity metal has been diffused into the copper film during annealing. In addition, the impurity metal is easily segregated, especially in the surface of the plated film. For this reason, it has been found that when the surface of the plated film is polished by CMP, a large number of impurity metals are removed, and thus the sufficient amount of impurity metals does not remain in the interconnect film after CMP. For this reason, it has not been possible to provide a region having a high concentration of the impurity metals in a desired place of the interconnect. On the other hand, there has been a problem that annealing is not performed after growth of the plated film, the grains do not grow, and thus the interconnect resistance increases.

According to the configuration of the invention, the first annealing before the plated metal film and the seed alloy film exposed to the outside of the concave portion is removed is performed for a short period of time, whereby it is possible to prevent excessive diffusion of the impurity metal, and to leave the sufficient amount of impurity metals in a portion which is not removed by the removal process. For this reason, at the time of the second annealing process after a redundant portion is removed by the removal process, the impurity metal is diffused within the copper along the inside of the grains and the grain boundary, and is unevenly distributed in the upper surface of the interconnect or the grain boundary in which stable existence thereof is possible. Hereby, at the time of applying current to the interconnect, it is possible to prevent copper from being diffused by the impurity metal such as Al, and to improve electromigration lifetime of the interconnect and stress migration lifetime.

In addition, according to the configuration of the invention, even when the processing time of the first annealing is set to a short period of time as described above, the grain growth of copper can be precipitated by raising the processing temperature by performing the first annealing at a high temperature. Hereby, it is possible to suppress an increase in the interconnect resistance.

Moreover, arbitrary combinations of the above-mentioned components, and ones obtained by conversion of the expression of the invention among methods, devices and the like are also effective as the aspect of the invention.

According to the invention, it is possible to improve electromigration lifetime of the interconnect and stress migration lifetime, while suppressing an increase in the interconnect resistance.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view illustrating the configuration of a semiconductor device according to an embodiment of the invention;

FIGS. 2A and 2B are process cross-sectional views illustrating a manufacturing procedure of the semiconductor device according to the embodiment of the invention;

FIGS. 3A and 3B are process cross-sectional views illustrating the manufacturing procedure of the semiconductor device according to the embodiment of the invention;

FIGS. 4A and 4B are process cross-sectional views illustrating the manufacturing procedure of the semiconductor device according to the embodiment of the invention;

FIGS. 5A and 5B are process cross-sectional views illustrating the manufacturing procedure of the semiconductor device according to the embodiment of the invention;

FIG. 6 is a flowchart illustrating the manufacturing procedure of the semiconductor device according to the embodiment of the invention;

FIG. 7 is a cross-sectional view illustrating the configuration of an interconnect according the embodiment of the invention; and

FIG. 8 is a cross-sectional view illustrating an interconnect according to the embodiment of the invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purpose.

Hereinafter, the embodiment of the invention will be described with reference to the accompanying drawings. In all the drawings, like elements are referenced by like reference numerals and descriptions thereof will not be repeated.

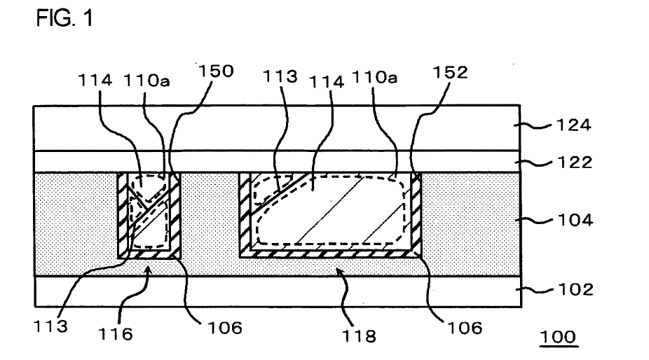

FIG. 1 is a cross-sectional view illustrating the configuration of a semiconductor device 100 according to the embodiment.

The semiconductor device 100 includes a semiconductor substrate (substrate) 102, an insulating interlayer 104 (insulating film) formed on the semiconductor substrate 102, a narrow-width interconnect 116 and a wide-width interconnect 118 formed, respectively, in an interconnect trench 150 and an interconnect trench 152 formed in the insulating interlayer 104, a cap film 122 formed on the insulating interlayer 104, and an insulating interlayer 124 formed thereon. Here, the semiconductor substrate 102 may be formed of, for example, a silicon substrate. Although not shown in the drawing, transistors and the like are formed on the semiconductor substrate 102. Another insulating film may be formed between the semiconductor substrate 102 and the insulating interlayer 104.

In the embodiment, the narrow-width interconnect 116 and the wide-width interconnect 118 are respectively composed of a barrier metal film 106 and an interconnect metal film 114. The barrier metal film 106 includes a high melting point metal such as, for example, Ti, W or Ta. As the preferred barrier metal film 106, for example, Ti, TiN, W, WN, Ta, TaN and the like are exemplified. In the embodiment, the barrier metal film 106 may be composed of a Ta film, a TaN film or a stacked film thereof. The interconnect metal film 114 contains copper as a major ingredient and contains an impurity metal different from copper. Here, as the impurity metal, for example, Al, Be, Mg, Zn, Pd, Ag, Cd, Au, Hg, Pt, Si, Zr, or Ti and the like are exemplified, and a single kind or two or more kinds thereof may be included. In the embodiment, the impurity metal may be Al. Al is preferably used as it is easy to handle because Al has been used as an interconnect material of the semiconductor device, and the behavior of which also has been understood as is used in the semiconductor device. In addition, grains of copper defined by a grain boundary 113 are formed in the interconnect metal film 114.

In the embodiment, as described later, the interconnect metal film 114 is configured so that the average concentration of the impurity metal in the surface thereof in a stacking direction is higher than the concentration of the impurity metal in the central portion thereof. In addition, the interconnect metal film 114 is configured so that the concentration of the impurity metal in the grain boundary 113 is higher than the concentration of the impurity metal within the grains. Further, the interconnect metal film 114 is configured so that the concentration of the impurity metal in the sidewall and the bottom face thereof is higher than that in other regions. In addition, the interconnect metal film 114 has a concentration profile, in the surface thereof, in which the concentration of the impurity metal increases extending from the central portion of the width direction to the sidewall. An impurity high concentration region 110a (outer region of the dashed line) defined by the dashed line in the drawing is a region the impurity concentration of which is high.

The insulating interlayer 104 may be configured using, for example, polyorganosiloxane such as hydrogen silsesquioxane (HSQ), methyl silsesquioxane (MSQ) or methylated hydrogen silsesquioxane (MHSQ), aromatic-containing organic materials such as polyarylether (PAE), divinyl siloxane bis-benzocyclobutene or Silk (registered trademark), and low-dielectric constant materials such as SOG (spin on glass), FOX(flowable oxide), parylene, CYTOP or benzocyclobutene (BCB). The insulating interlayer 124 may be composed of the same materials as the insulating interlayer 104. Although not shown here, the same interconnects as the narrow-width interconnect 116 or the wide-width interconnect 118 and the like may be also formed within the insulating interlayer 124. The cap film 122 may be, for example, an SiCN film.

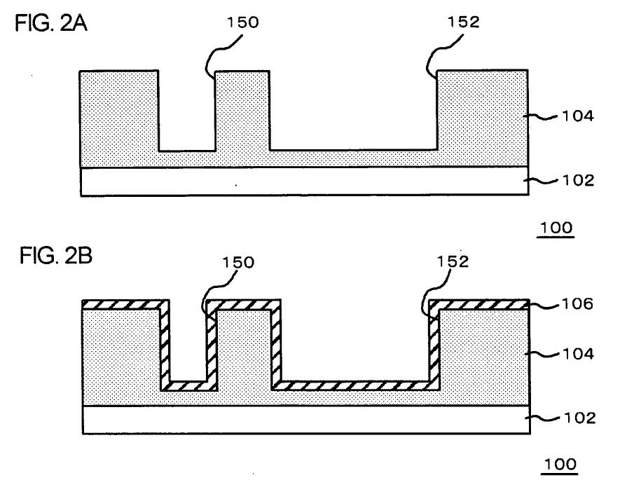

Next, the manufacturing procedure of the semiconductor device 100 according to the embodiment will be described. FIGS. 2A to 5B are process cross-sectional views illustrating the manufacturing procedure of the semiconductor device 100.

First, the interconnect trench 150 and the interconnect trench 152 are formed in the insulating interlayer 104 (FIG. 2A). Subsequently, the barrier metal film 106 is formed on the whole surface of the insulating interlayer 104 by, for example, a sputtering method (FIG. 2B). Here, the barrier metal film 106 is formed on the bottom faces and the sidewalls of the interconnect trench 150 and the interconnect trench 152, and the surface of the insulating interlayer 104. Here, the barrier metal film 106 may be a stacked film of a Ta film and a TaN film.

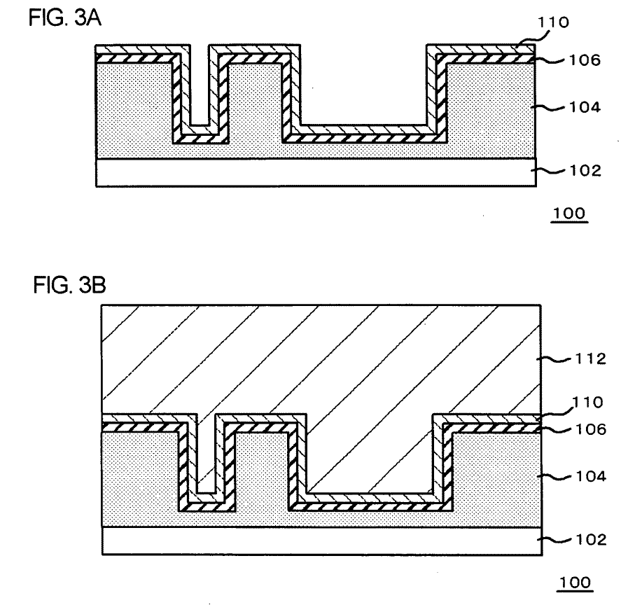

Subsequently, a seed alloy film 110 is formed on the whole surface of the barrier metal film 106 by the sputtering method using an alloy including copper and the above-mentioned impurity metal as a target (FIG. 3A). In the embodiment, a CuAl alloy target may be used. In addition, the concentration of the impurity metal may be equal to or more than 0.5 wt %. Hereby, it is possible to leave the sufficient amount of impurities in the seed alloy film 110 even after CMP, and to provide a region of which the concentration of the impurity metal is above a certain degree of value in a desired place of the interconnect. In addition, the concentration of the impurity metal in the seed alloy film 110 may be set to a degree that when a plating film is formed afterward, the seed alloy film 110 is able to satisfactorily function as a seed, for example, may be set to be equal to or less than 10 wt %.

Subsequently, a plated metal film 112 is formed by a plating method to fill the insides of the interconnect trench 150 and the interconnect trench 152 (FIG. 3B). The plated metal film 112 may contain copper as a major ingredient. Meanwhile, although the plated metal film 112 may also include some kind of impurity metals different from copper, the impurity concentration is set to the lower concentration than that of the seed alloy film 110.

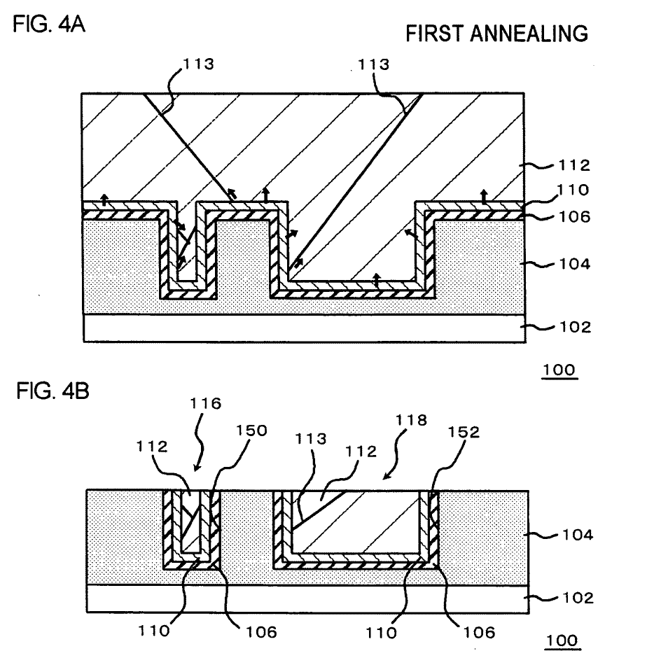

Next, the first annealing at a high temperature and a short period of time is performed and (FIG. 4A). In the embodiment, the first annealing may be performed in an N₂/H₂ atmosphere. Hereby, it is possible to prevent the copper in the plated metal film 112 from being oxidized and corroded.

In addition, processing time of the first annealing may be set to, for example, ten minutes or less, preferably five minutes or less, more preferably one minute or less. The impurity metal in the seed alloy film 110 is diffused to the inside of the grains in the plated metal film 112 or to the grain boundary 113 by the annealing process. However, in the embodiment, the first annealing is performed for such a short period of time, whereby it is possible to prevent the impurity metal from being excessively diffused from the seed alloy film 110 into the plated metal film 112 in this step. Further, in the embodiment, the barrier metal film 106 for preventing diffusion of copper or aluminum is formed on the bottom faces and sidewalls of the interconnect trench 150 and the interconnect trench 152. For this reason, the materials constituting the seed alloy film 110 are not diffused into the insulating interlayer 104, thereby allowing them to be maintained within the interconnect trench 150 and the interconnect trench 152. Hereby, in this step, a large portion of the seed alloy film 110 is maintained in a state where it exists in situ in the surface of the barrier metal film 106 of the interconnect trench 150 and the interconnect trench 152.

In addition, the processing temperature of the first annealing may be set to, for example, 200° C. or higher, more preferably 300° C. or higher. The first annealing is performed at such a high temperature, thereby allowing grain growth of copper to be precipitated. In the embodiment, even when the processing time of the first annealing is set to a short period of time as described above, the grain growth of copper can be precipitated by raising the processing temperature. In addition, since the grain growth of copper progresses more rapidly than the diffusion of the impurity metal by performing the first annealing process at a high temperature and a short period of time, the impurity metal is easily segregated by the grain boundary 113. When the impurity metal is included in the seed alloy film 110, and resistance of the impurity metal is higher than that of copper, there may be a concern that interconnect resistance may become higher than the case where copper alone is used. However, in the embodiment, it is possible to suppress an increase in the interconnect resistance by increasing the grain size.

After this, the plated metal film 112, the seed alloy film 110, and the barrier metal film 106 which are exposed to the outside of the interconnect trench 150 and the interconnect trench 152 are removed by the CMP. Hereby, the narrow-width interconnect 116 and the wide-width interconnect 118 are formed (FIG. 4B).

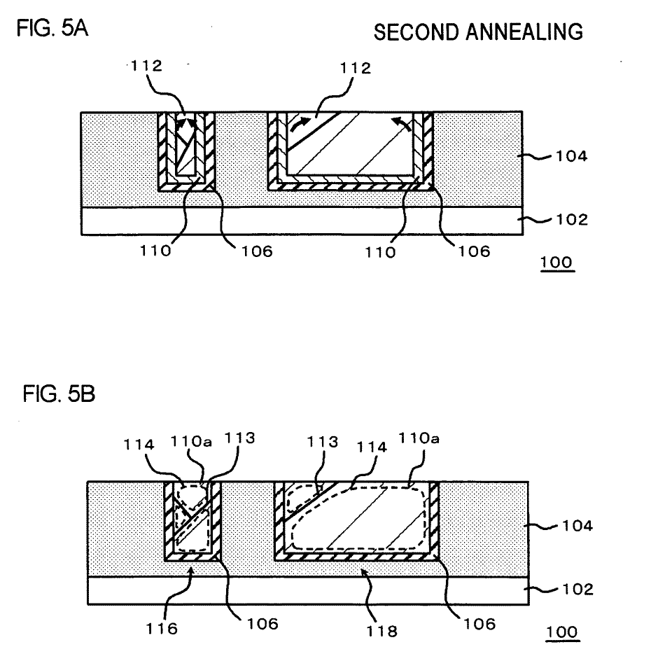

Next, the second annealing is performed (FIG. 5A). Here, the processing temperature of the second annealing may be set to, for example, 350° C. or so. In addition, the processing time of the second annealing may be set to be longer than that of the first annealing, and may be set to, for example, thirty minutes or so. Hereby, the impurity metal in the seed alloy film 110 is diffused into the plated metal film 112.

In the embodiment, the first annealing before the CMP is performed for a short period of time, whereby it is possible to leave the sufficient amount of impurity metals in a portion which is not removed by the CMP. For this reason, at the time of the second annealing process after a redundant portion is removed by the CMP, the impurity metal is diffused within the copper along the inside of the grains and the grain boundary 113, and is unevenly distributed in the upper surface of the interconnect or the grain boundary 113 in which stable existence thereof is possible. At this time, since the redundant portion is removed in the interconnect metal film 114, it is possible to provide the impurity high concentration region 110a of which the concentration of the impurity metal is above a certain degree of value in a desired place of the narrow-width interconnect 116 and the wide-width interconnect 118 (FIG. 5B).

The interconnect metal film 114 may have a configuration as follows by the above-mentioned procedure.
(1) The impurity metal is diffused from the seed alloy film 110, and has a high concentration in the upper surface of the interconnect in which the energetically stable existence thereof is possible. For this reason, the average concentration of the impurity metal in the surface in the stacking direction is higher than the concentration of the impurity metal in the central portion. In this manner, it is possible to raise the stress migration resistance by raising the impurity concentration in the interconnect surface. Here, the average content (atom %) of the impurity metal in the surface of the interconnect metal film 114 can be set to be, for example, equal to or more than 1.2 times the average content of the impurity metal in the central portion. By setting the difference to such a degree, it is possible to raise stress migration of the interconnect metal film 114, and to maintain low resistance of the interconnect metal film 114.
(2) The impurity metal is diffused from the seed alloy film 110, is diffused within the copper along the inside of the grains and the grain boundary 113, and has a high concentration in the grain boundary 113 in which the energetically stable existence thereof is possible. For this reason, the concentration of the impurity metal in the grain boundary 113 is higher than the concentration of the impurity metal within the grains. In this manner, it is possible to raise the electromigration resistance and the stress migration resistance by raising the impurity concentration in the grain boundary 113.
(3) Since the impurity metal is diffused from the seed alloy film 110, the concentration of the impurity metal in the sidewall and the bottom face becomes higher than that in other regions. Hereby, since drift of Cu atoms is suppressed, it is possible to raise the electromigration resistance and the stress migration resistance.
(4) Similarly, since the impurity metal is diffused from the seed alloy film 110, the concentration of the impurity metal becomes high in the surface extending to the sidewall direction of a position near to the seed alloy film 110 formed on the sidewall. For this reason, the interconnect metal film has a concentration profile, in the surface, in which the concentration of the impurity metal becomes high extending from the central portion of the width direction to the sidewall. In other words, in the interconnect surface, the impurity metal has a higher concentration as it gets nearer to the side, and particularly an overhang portion of the impurity high concentration region 110a having a high concentration is formed in the corner portions. Hereby, it is possible to prevent a short circuit between the interconnects, and to improve TDDB lifetime. In addition, the interconnect is connected to a via in the central portion of the surface. In the embodiment, it is also possible to reduce the contact resistance of the interconnect with the via by lowering the concentration of the impurity metal in the central portion of the interconnect surface. However, in the embodiment, the interconnect can be also configured to have a higher impurity concentration in the central portion of the surface than that in the central portion in the stacking direction, and is configured to sufficiently maintain the stress migration resistance.

After this, the cap film 122 is formed on the insulating interlayer 104. The insulating interlayer 124 is further formed thereon. Hereby, the semiconductor device 100 of the configuration as shown in FIG. 1 is obtained. After this, vias or interconnects may be formed in the insulating interlayer 124 by the similar procedure. Then, the semiconductor device 100 having a multilayer interconnect structure can be formed.

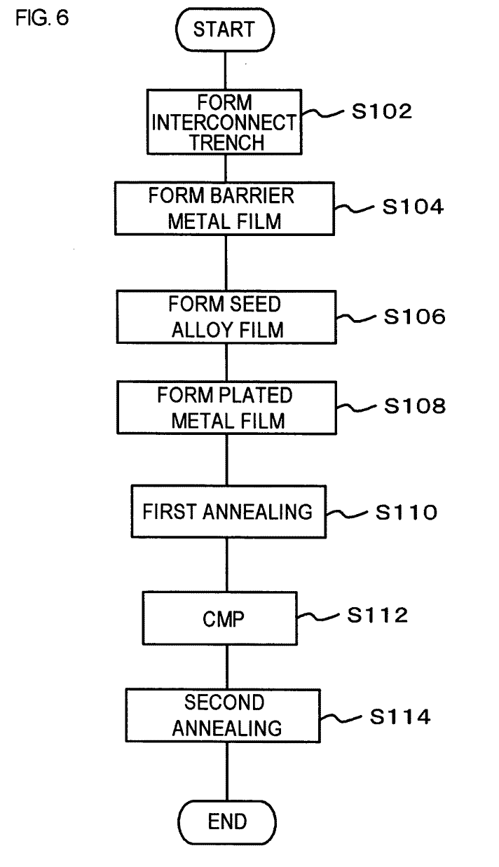

FIG. 6 is a flowchart illustrating the manufacturing procedure of the semiconductor device according to the embodiment.

First, the interconnect trenches such as the interconnect trench 150 and the interconnect trench 152 are formed in the insulating interlayer 104 (S102). Subsequently, the barrier metal film 106 is formed on the whole surface of the insulating interlayer by, for example, the sputtering method (S104). Next, the seed alloy film 110 is formed on the whole surface of the barrier metal film 106 (S106).

Subsequently, the plated metal film 112 is formed on the seed alloy film 110 by the plating method to fill the insides of the interconnect trench 150 and the interconnect trench 152 (S108). Next, the first 20, annealing process is performed at a high temperature and a short period of time (S110).

After that, the plated metal film 112, the seed alloy film 110 and the barrier metal film 106 which are exposed to the outside of the interconnect trench 150 and the interconnect trench 152 are removed by the CMP, and the narrow-width interconnect 116 and the wide-width interconnect 118 are formed (S112). After that, the second annealing is performed (S114).

Meanwhile, although the second annealing described in the above-mentioned embodiment may be performed whenever the interconnect of each layer is formed for the purpose of diffusing the impurity metal, it is possible to perform various types of other annealing processes at the time of forming the multilayer interconnect structure without adding a special annealing process. In the embodiment, it is important to perform the first annealing before the CMP at the time of forming each interconnect at a high temperature and a short period of time. On the other hand, even though processing time or processing temperature is not strictly managed in the second annealing process after the CMP, it is possible to achieve the desired configuration as stated above, because the impurity metal is moved to an energetically stable place.

### Example 1

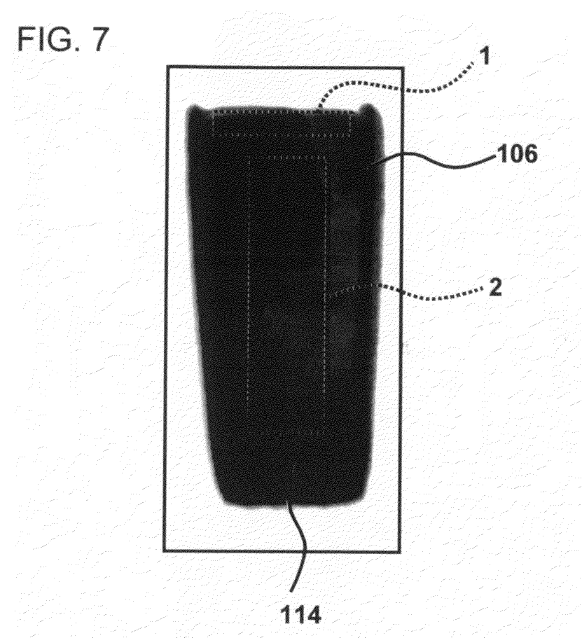

The semiconductor device was manufactured by the manufacturing procedure of the semiconductor device described with reference to FIGS. 1 to 5B. FIG. 7 is a cross-sectional view (BF-STEM image) illustrating the configuration of the narrow-width interconnect 116. Herein, the interconnect width was set to 50 nm. A stacked film (total film thickness of 7 nm) of a Ta film and a TaN film was used as the barrier metal film 106. In addition, Al was used as the impurity metal. The content of Al was set to 0.5 wt %. The film thickness of the seed alloy film 110 was set to 5 nm. The first annealing condition was set to a processing time of thirty seconds and a processing temperature of 350° C. In addition, the second annealing condition was set to a processing time of thirty minutes and a processing temperature of 350° C.

The elemental analysis was performed by the energy dispersive X-ray spectrometer (EDX), using the interconnect surface surrounded by the dashed line “1” and the central portion surrounded by the dashed line “2” of FIG. 7, respectively, as analysis regions. The content of Al with respect to all the elements in each of the analysis regions was as follows.

Analysis point 1: 0.97 atom %

Analysis point 2: 0.48 atom %

As mentioned above, the average concentration (content) of Al (impurity metal) in the interconnect surface was about two times higher than the average concentration (content) of Al in the central portion.

### Example 2

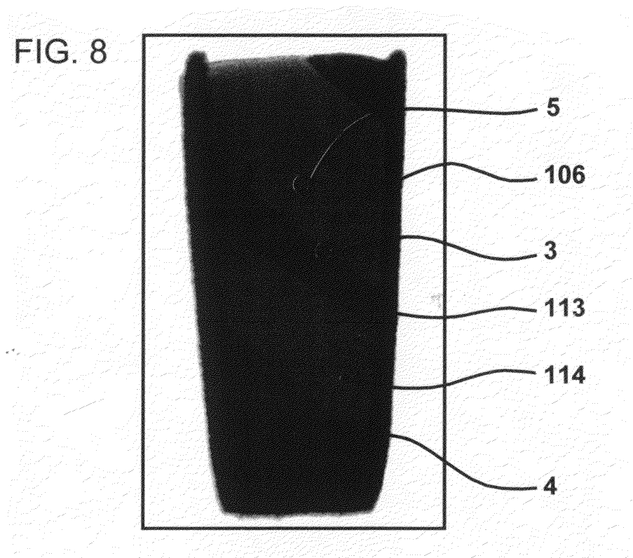

Similarly to Example 1, the semiconductor device was manufactured by the manufacturing procedure of the semiconductor device described with reference to FIGS. 1 to 5B. FIG. 8 is a cross-sectional view (BF-STEM image) illustrating the configuration of the narrow-width interconnect 116. The condition was the same as Example 1. The darker shaded area in the interconnect metal film 114 of FIG. 8 is a place in which the grain boundary 113 is distributed. “3” and “4” of FIG. 8 exist in the grain boundary 113. “5” exists in the inside of the grains of the interconnect metal film 114.

The elemental analysis of the cross section of the narrow-width interconnect 116 was performed by the EDX. The elemental analysis was performed using the grain boundary indicated by “3”, the grain boundary indicated by “4”, and the inside of the grains indicated by “5” of FIG. 8, respectively, as the analysis points. The respective content of Al to all the elements in the respective analysis regions were as follows.

Analysis point 3: 0.21 atom %

Analysis point 4: 0.23 atom %

Analysis point 5: 0.03 atom %

As described above, the average concentration of Al (impurity metal) in the grain boundary 113 was about seven times higher than the concentration (content) of Al in the inside of the grains. Here, since a surface analysis is performed in Example 1, although a point analysis is performed in Example 2, it is considered that the content detected in Example 1 is higher.

Next, the effect of the semiconductor device 100 in the embodiment will be described.

As described above, in the embodiment, the first annealing before the CMP is performed for a short period of time, whereby it is possible to leave the sufficient amount of impurity metals in a portion which is not removed by the CMP. For this reason, at the time of the second annealing process after a redundant portion is removed by the CMP, the impurity metal is diffused within the copper along the inside of the grains and the grain boundary 113, and is unevenly distributed in the upper surface of the interconnect or the grain boundary 113 in which stable existence thereof is possible. Hereby, the impurity metal can be set to exist at a high concentration above a certain degree in the upper surface of the interconnect or the grain boundary 113. For this reason, at the time of applying current to the interconnect, it is possible to prevent copper from being diffused by the impurity metal such as Al, and to improve electromigration lifetime of the interconnect and stress migration lifetime.

As described above, although the embodiments of the invention have been set forth with reference to the drawings, they are merely illustrative of the invention, and various configurations other than stated above can be adopted.

The narrow-width interconnect 116 and the wide-width interconnect 118 may be applied to any of a single damascene method or a dual damascene method.

It is apparent that the present invention is not limited to the above embodiment, and may be modified and changed without departing from the scope and spirit of the invention.

What is claimed is:

1. A method of manufacturing a semiconductor device, comprising:
forming a barrier metal film including a high melting point metal in a concave portion formed in an insulating film formed over a substrate;
forming a seed alloy film including copper and an impurity metal different from the copper over said barrier metal film so as to fill a portion of said concave portion;
forming a plated metal film containing copper as a major ingredient over said seed alloy film so as to fill said concave portion;
first heat-treating said seed alloy film and said plated metal film at 200° C. or higher and for ten minutes or less;
removing said plated metal film, said seed alloy film, and said barrier metal film which are exposed to the outside of said concave portion, after said first heat-treating; and
second heat-treating said seed alloy film and said plated metal film.

2. The method of manufacturing of the semiconductor device as set forth in claim 1, wherein said impurity metal is Al, Be, Mg, Zn, Pd, Ag, Cd, Au, Hg, Pt, Si, Zr, or Ti.

3. The method of manufacturing of the semiconductor device as set forth in claim 1, wherein said impurity metal is Al.

4. The method of manufacturing of the semiconductor device as set forth in claim 1, wherein the high melting point metal constituting said barrier metal film is Ta.

5. The method of manufacturing of the semiconductor device as set forth in claim 1, wherein said barrier metal film is made up of a Ta film, a TaN film or a stacked film thereof.

6. The method of manufacturing of the semiconductor device as set forth in claim 1, wherein said first heat-treating is performed under an atmosphere of N₂/H₂.

7. The method of manufacturing of the semiconductor device as set forth in claim 1, wherein in said forming of the seed alloy film, said seed alloy film includes said impurity metal equal to or more than 0.5 wt %.

8. The method of manufacturing of the semiconductor device as set forth in claim 1, wherein in said first heat-treating, said seed alloy film and said plated metal film are heat-treated for one minute or less.

9. The method of manufacturing of the semiconductor device as set forth in claim 1, wherein in said second heat-treating, the processing time thereof is longer than that of said first heat-treating.

10. A semiconductor device comprising:
a substrate;
an insulating film formed over said substrate;
a barrier metal film which is formed in the bottom face and the sidewall of a concave portion formed in said insulating film, and contains a high melting point metal; and
an interconnect metal film formed over said barrier metal film within said concave portion, and containing copper as a major ingredient and an impurity metal different from the copper, grains of copper being formed therein,
wherein said interconnect metal film is configured so that in a stacking direction, the average concentration of said impurity metal in the surface thereof is higher than the concentration of said impurity metal in the central portion thereof, and the concentration of said impurity metal in the grain boundary is higher than the concentration of said impurity metal in the inside of the grains, said interconnect metal film having a concentration profile in which the concentration of said impurity metal becomes high, in said surface, extending from the central portion of the width direction to the sidewall.

11. The semiconductor device as set forth in claim 10, wherein said interconnect metal film is configured so that the concentration of said impurity metal is higher than that of other regions in the sidewall and the bottom face thereof.

12. The semiconductor device as set forth in claim 10, wherein said impurity metal is Al, Be, Mg, Zn, Pd, Ag, Cd, Au, Hg, Pt, Si, Zr, or Ti.

13. The semiconductor device as set forth in claim 10, wherein said impurity metal is Al.

14. The semiconductor device as set forth in claim 10, wherein the high melting point metal consticuting said barrier metal film is Ta.

15. The semiconductor device as set forth in claim 10, wherein said barrier metal film is made up of a Ta film, a TaN film or a stacked film thereof.

16. The semiconductor device as set forth in claim 10, wherein said interconnect metal film is configured so that in the stacking direction, the average content (atom %) of said impurity metal in the surface thereof is above 1.2 times the average content of said impurity metal in the central portion thereof.
